(19) United States
(12) Patent Application Publication
(10) Pub. No.: US 2016/0073503 A1
(43) Pub. Date: Mar. 10, 2016

(54) STRAP BAND INCLUDING ELECTRODES FOR WEARABLE DEVICES AND FORMATION THEREOF

(71) Applicants: Chris Singleton, San Francisco, CA (US); Piyush Savalia, San Francisco, CA (US); Prasad Panchalan, San Francisco, CA (US); Sylvia Hou-Yan Cheng, San Francisco, CA (US); Sheila Nabanja, San Francisco, CA (US); liyas Mohammad, San Francisco, CA (US); Sumit Sharma, San Francisco, CA (US)

(72) Inventors: Chris Singleton, San Francisco, CA (US); Piyush Savalia, San Francisco, CA (US); Prasad Panchalan, San Francisco, CA (US); Sylvia Hou-Yan Cheng, San Francisco, CA (US); Sheila Nabanja, San Francisco, CA (US); liyas Mohammad, San Francisco, CA (US); Sumit Sharma, San Francisco, CA (US)

(73) Assignee: AliphCom, San Francisco, CA (US)

(21) Appl. No.: 14/480,070

(22) Filed: Sep. 8, 2014

(51) Int. Cl. H05K 1/18; H05K 1/03; H05K 3/32; H05K 3/00; H05K 3/30; H05K 1/02; H05K 1/11

(52) U.S. Cl. CPC H05K 1/181; H05K 1/0283; H05K 1/0393; H05K 1/118; H05K 1/0326; H05K 3/0058; H05K 3/305; H05K 3/326; H05K 2203/1305; H05K 2201/058; H05K 2201/042; H05K 2201/10151; H05K 2201/10166; H05K 2203/1147

(57) ABSTRACT

A strap band including a flexible wire bus having electrodes and wires coupled with the electrodes is described. The wire bus may be include in a strap band formed by molding an inner strap, mounting the wire bus in the inner strap, and injection molding an outer strap over the inner strap and wire bus to form a strap band. The electrodes may be positioned on the inner strap to accommodate a target range of a body portion the strap band may be worn on. A material of the strap band and a material the wire bus may be selected to allow a low coefficient of friction between the wire bus and strap band so that loads applied to the strap band may not be coupled with the wire bus or cause damage to wires due to pull and/or torsional load forces applied to the strap band.

### FIELD

Embodiments of the present application relate generally to hardware, software, wired and wireless communications, RF systems, wireless devices, wearable devices, biometric devices, health devices, fitness devices, and consumer electronic (CE) devices.

### BACKGROUND

Devices that may be used to detect and track motion, diet, sleep patterns, biometric data, fitness, and other activities of a user, must often undergo stress and strain caused by torsional forces, sheer forces, stretching forces, etc., applied to the device by its user. Moreover, components carried by the device may be susceptible to moisture, chemicals, vibration, and shock that occur during use of the device. For example, if the device is not effectively sealed from water intrusion, then electrical systems of the device may be damaged when the device is exposed to water. Components and/or electrical connections between components may be damaged or have electrical continuity compromised by the aforementioned forces applied to the device. Biometric and/or other types of sensors that may be included in the device may require consistent positioning and/or contact with portions of a user's body, such as the skin, for example. A band or strap used to connect the device with a user's body may be too stiff, uncomfortable to wear, or not easily adjusted to match the user's body.

Accordingly, there is a need for systems, apparatus and methods that provide devices that are rugged, reliable, sealed against the environment, comfortable to wear, and adjustable.

### BRIEF DESCRIPTION OF THE DRAWINGS

Various embodiments or examples (“examples”) are disclosed in the following detailed description and the accompanying drawings:

FIG. 1 depicts various examples of a wire bus and components coupled with the wire bus;

FIG. 2 depicts top, side, and bottom plan views of a wire bus;

FIG. 3 depicts one example of a wire bus including a wire bridge;

FIG. 4 depicts one example of a wire bus including a substrate having an antenna coupled with a near field communication chip;

FIG. 5 depicts examples of relative spacing and dimensions of electrodes included in a wire bus;

FIG. 6 depicts examples of wire routing and connection with pads included in a wire bus;

FIG. 7 depicts a side view of one example of an electrode, a skirt, and a pad that may be included in a wire bus;

FIG. 8 depicts profile views of other examples of an electrode, a skirt, and a pad that may be included in a wire bus;

FIG. 9 depicts various views of yet other examples of an electrode, a skirt, and a pad that may be included in a wire bus;

FIG. 10 depicts one example of an assembly order of a strap band that includes a wire bus, an inner strap and an outer strap;

FIG. 11 depicts one example of a wire bus being coupled with an inner strap;

FIG. 12 depicts one example of an outer strap being formed on wire bus coupled with an inner strap;

FIG. 13 depicts top, side and bottom views of one example of a strap band that includes an encapsulated wire bus and sealed electrodes;

FIG. 14 depicts examples of fastening hardware that may be coupled with a strap band;

FIG. 15 depicts one example of a flow diagram for a method of fabricating a wire bus;

FIG. 16 depicts one example of a flow diagram for a method of fabricating a strap band that includes a wire bus; and

FIG. 17 depicts various views of a strap band.

Although the above-described drawings depict various examples of the invention, the invention is not limited by the depicted examples. It is to be understood that, in the drawings, like reference numerals designate like structural elements. Also, it is understood that the drawings are not necessarily to scale.

### DETAILED DESCRIPTION

Various embodiments or examples may be implemented in numerous ways, including but not limited to implementation as a device, a wireless device, a system, a process, a method, an apparatus, a user interface, or a series of executable program instructions included on a non-transitory computer readable medium. Such as a non-transitory computer readable medium or a computer network where the program instructions are sent over optical, electronic, or wireless communication links and stored or otherwise fixed in a non-transitory computer readable medium. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For clarity, technical material that is known in the technical fields related to the examples has not been described in detail to avoid unnecessarily obscuring the description.

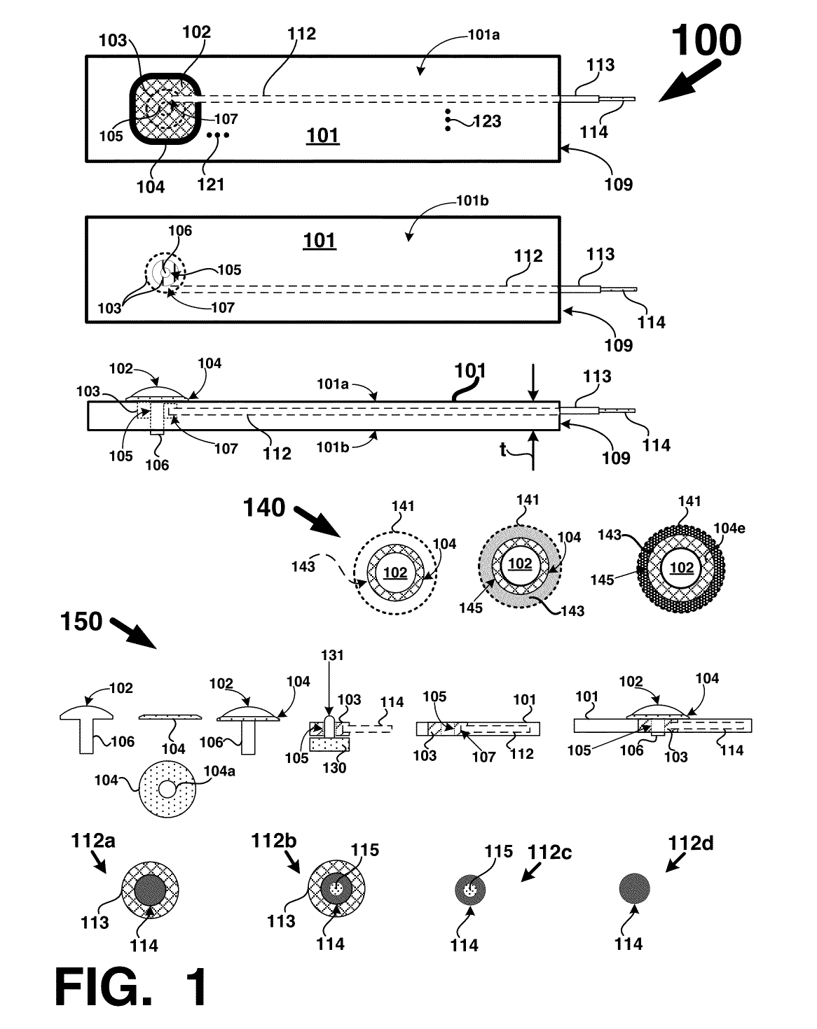

Reference is now made to FIG. 1 where various examples of a wire bus 100 and components coupled with the wire bus 100 are depicted. Wire bus 100 may include a bus substrate 101 that may be made from a flexible and electrically non-conductive material including but not limited to a thermoplastic elastomer and rubber, for example. A side view of bus substrate 101 depicts a wire 112 encapsulated between an upper surface 101a and a lower surface 101b of the bus substrate 101. Wire 112 may be coupled 107 with a pad 103 (shown in dashed line) and pad 103 may be coupled with an electrode 102. Electrode 102 may be coupled with a skirt 104 and may include a pin 106 that is positioned in an aperture 105 of the pad 103. A dimension of the pin 106 may be selected to be slightly greater than a diameter of the aperture 105 so that when the pin 106 is inserted into the aperture 105 a press fit is established between the pin 106 and aperture 105. Press fitting the pin 106 into the pad 103 may provide for a pressure fit that retains the electrode 102 in contact with the pad 103 and may also provide for a low electrical resistance connection between the electrode 102 and pad 103. The press fit may also be operative to securely couple the skirt 104, pad 103 and electrode with one another. Crimping, soldering, or other techniques may be used to couple the pad 103 and the electrode 102 with each other, and the press fit is one non-limiting example of how the pad 103 and electrode may be coupled with each other. A portion of pin 106 may extend outward of the lower surface 101b of the bus substrate 101. After the wire bus 100 has been fabricated (e.g., by injection molding) the exposed portion of the pin 106 may be used for electrical continuity testing of one or more of the pad 103, the electrode 104, and wire 112.

Wire 112 may be connected with a portion of pad 103 using soldering, crimping, wrapping, or welding for example. As one example, wire 112 may be laser welded to a portion of pad 103. Pad 103, the electrode 102 or both may be made from an electrically conductive material including but not limited to a metal, a metal alloy, copper, gold, silver, platinum, aluminum, stainless steel, and alloys of those metals. As one example, pad 103 may be a copper (Cu) washer. Wire 112 may include insulation 113 that may be stripped to expose a conductor 114 that may be connected with the pad 103. Wire 112 may be routed along a path in the wire bus 100 and may exit the wire bus 100 at a distal end 109. A portion of the wire 112 positioned at the distal end 109 may be stripped to expose conductor 114 and the conductor 114 may be tinned (e.g., with solder) in preparation for connecting the conductor 114 with another structure, such as an electrical node, printed circuit board (PCB) trace, or circuitry, for example. A portion of the wire 112 positioned at the distal end 109 may be dressed for subsequent connection with other structures. There may be more electrodes 102, pads 103, skirts 104 and wires 112 than depicted as denoted by 121 and 123.

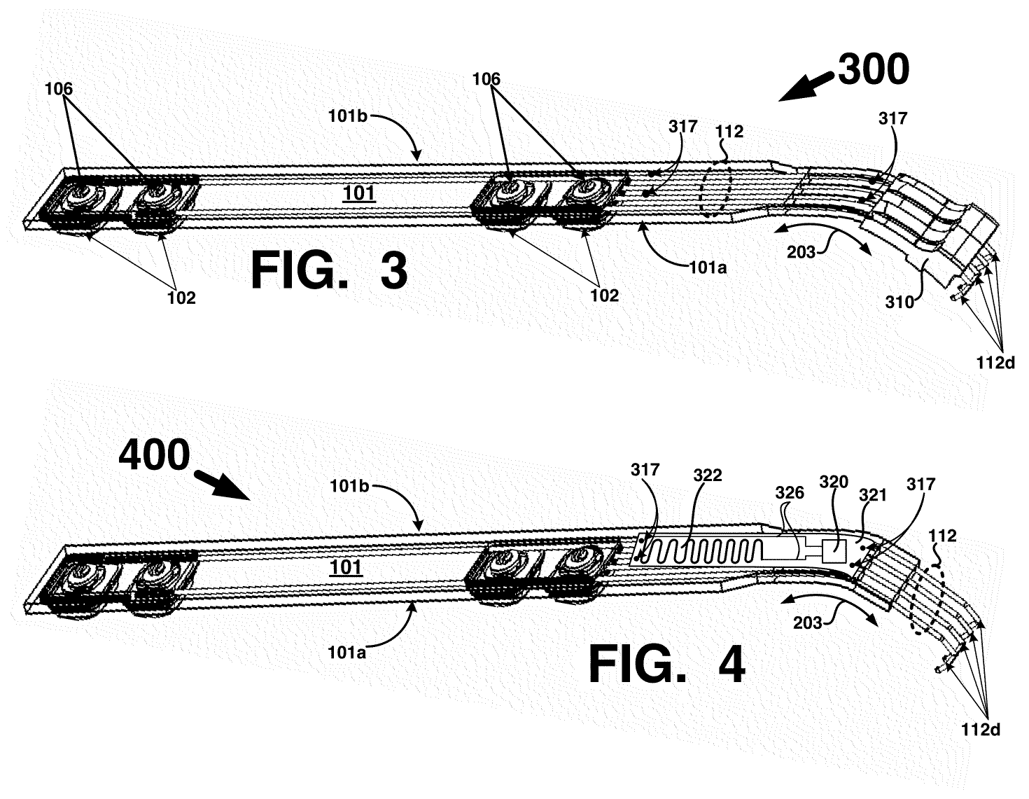

Bus substrate 101 may include alignment structures (e.g., see 307 in FIGS. 3 and 4) that may be used to mount other components to the wire bus 100, such as an antenna and a near field communication chip, for example. Bus substrate 101 may include a thickness t that may be 1 mm or less in thickness. The material used for bus substrate 101 may be selected to sustain a continuous pull load of about 2 kg and to sustain a maximum pull load of about 8 kg. Actual force loads may be application dependent and the foregoing are non-limiting examples.

In example 140, electrode 102 and skirt 104 may be positioned relative to an aperture 141 of an inner strap of a strap band (not shown). A material 143, such as a material used to form an outer strap of the strap band (e.g., via injection molding). Wire bus 100, skirt 104, or structures in a mold may include channels, ports, or other structures configured to provide a path for material 143 to enter into aperture 141. From left to right in example 140, material 143 (e.g., a thermoplastic elastomer) enters into aperture 141, fills the aperture 141 and connects with skirt 104 along an interface 145. Skirt 104 may be made from a material that interfaces with material 143 to establish a seal between the skirt 104 and the aperture 141. A temperature of material 143 may be operative to heat skirt 104 and the heat may be operative to form a seal between the electrode 102 and skirt 104, skirt 104 and aperture 141 or both. Material 143 may not interface with the electrode 102 (e.g., a metal material for electrode 102) and skirt 104 may be operative as a material that interfaces with electrode 102 and with material 143. For example, skirt 104 may be made from a polycarbonate material. In some examples, skirt 104 may expand in dimension when contacted by material 143 or heat in material 143 as denoted by 104e.

In example 150, electrode 102 may include a pin 106 and skirt 104 may include an aperture 104a through which the pin 106 may be inserted. A mold in which the wire bus 100 is molded or a jig may include a support structure 130 having a post 131 upon which the pad 103 is mounted. Wire 112 (e.g., stripped to expose conductor 114) may be connected with the pad 103 by soldering, crimping, wire wrapping, welding, or by application of an electrically conductive adhesive or epoxy, for example. A material for the bus substrate 101 may be formed over the pad 103 and wire 112. Post 131 may prevent the material from entering into the aperture 105 of the pad 103 so that in a subsequent processing step, pin 106 of electrode 102 and skirt 104 may be connected with the pad 103. As described above, a pressure or friction fit may be used to connect the pad 103 with the pin 106 of the electrode 102.

Examples 112a-112d depict various configurations for wire 112. In example 112a, wire 112 may include a conductor 114 surrounded by an insulator 113. In example 112b, wire 112 may include a conductor 114 surrounded by an insulator 113 and the conductor 114 surrounding a core 115 (e.g., a concentrically positioned core). Core 115 may be made from a high strength material such as a composite, Kevlar, fibers, carbon fiber, or the like, for example. Core 115 may be electrically conducting or electrically non-conducting. Core 115 may be used to structurally strengthen wire 112 against forces that may be caused by stretching wire bus 100 or a strap band that includes the wire bus 100. In example 112c, wire 112, sans insulation 113, may include the conductor 114 surrounding the core 115. In example 112d, wire 112 may include a conductor 114 (e.g., sans insulation 113 and core 115).

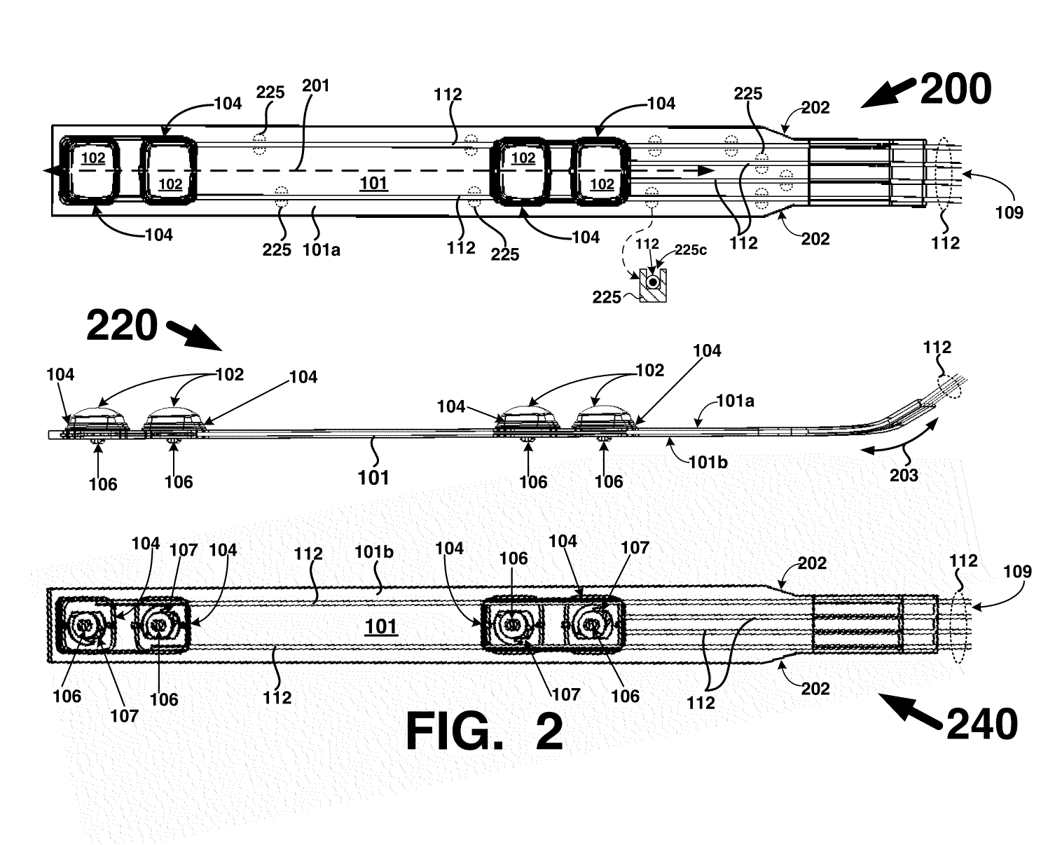

Turning now to FIG. 2, where top, side, and bottom plan views of a wire bus 100 are depicted. In a top view 200, electrodes 102 may be positioned on bus substrate in alignment with an axis 201. There may be more or fewer electrodes 102 disposed on bus substrate 101 than depicted and those electrodes 102 may be positioned in alignment with each other or some or all of the electrodes 102 may not be aligned with one another. Bus substrate 101 may have a different shape than depicted. For example, bus substrate 101 may have a taper 202 in its width. Wires 112 may be routed along a path in the bus substrate 101. The path may be determined by one or more wire guides 225 (depicted in dashed line) positioned in a mold or jig (not shown) that may be used to form the wire bus 100. Wire guide 225 may include a slot or channel 225c in which a portion of the wire 112 may be positioned. Side portions of electrodes 102 may be coupled with the skirt 104.

In a side view 220, a portion of the pins 106 of electrodes 102 may extend outward of lower surface 101b of bus substrate 101. In other examples the pins may not extend outward of lower surface 101b or may be cut, trimmed, grounded down or otherwise machined to be flush with or inset from lower surface 101b. Wire bus 100 may be formed from a material and may include components (e.g., core-reinforced wires) configured to allow flexing, pulling, stretching, twisting of the wire bus 100 as denoted by 203. The material for bus substrate 101 and its associated components may be selected to withstand a range of torsional loads that may be applied to the wire bus 100 and/or strap bands the wire bus 100 is positioned in.

In a bottom view 240, wires 112 may be coupled 107 with their respective pads 103 and the pads 103 may include a connection portion configured to receive the wire 112. Pads 103 may also include a flat (as will be described below) that allows one of the wires 112 to be routed past the pad 103 to another pad 103.

Moving now to FIG. 3 where depicts one example 300 of a wire bus 100 including a wire bridge 310 is depicted. The wire bridge 310 may be operative to position the wires 112 for attachment to another structure and may also be used to dress the wires 112 into a configuration for connection to another structure. A surface of the wire bus 100 may include one or more structures 317 configured to receive a component to be connected with the wire bus 100. Structures 317 may include a post, a pillar, a notch, a groove, etc., for example.

Moving down to FIG. 4 where one example 400 of the lower surface 101b of the wire bus 100 including a substrate 321 having an antenna 322 coupled 326 with a near field communication chip 320. Substrate 321 may be a flexible substrate that may be mounted to wire bus 100 using the structures 317. For example, structure 317 may be posts and substrate 321 may include apertures that match positions with and mate with structures 317. Other components may be coupled with wire bus 100 and the above mentioned substrate 321 is a non-limiting example. Components coupled with wire bus 100 may include wires or other types of interconnect structures that may be connected with other components.

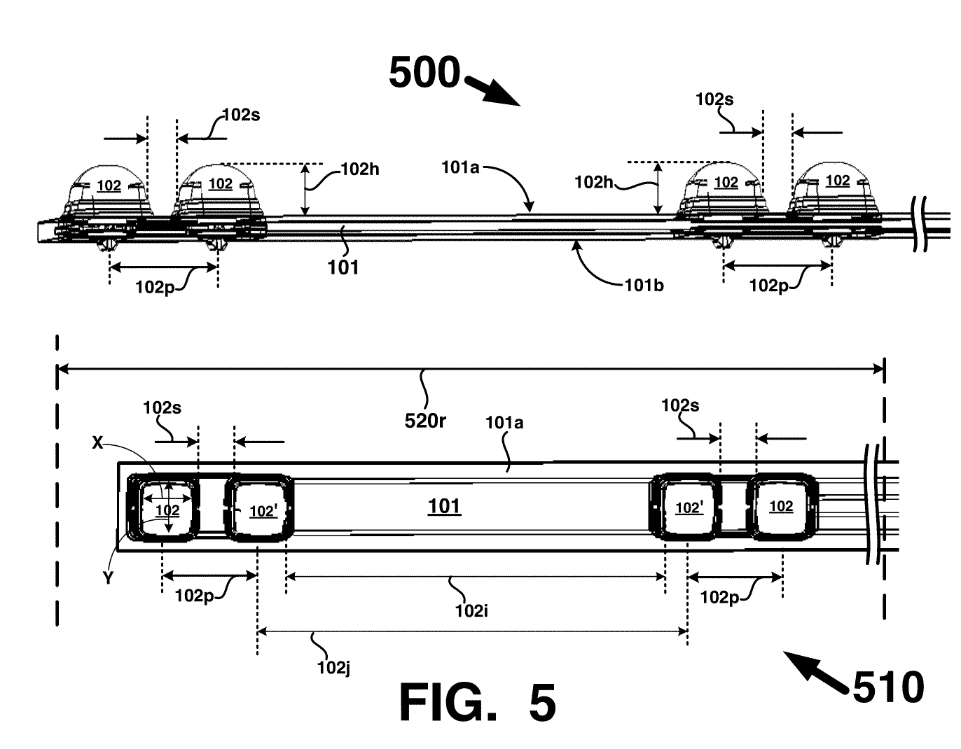

Referring now to FIG. 5 where examples of relative spacing and dimensions of electrodes included in a wire bus are depicted. In example 500, in a side view of wire bus 100, electrodes 102 may be positioned relative to one another by a spacing 102s. In other examples, electrodes 102 may be spaced apart from one another by a pitch 102p (e.g., as measured between centers of pins 106). Electrodes 102 may have a height 102h (e.g., as measured from upper surface 101a to an uppermost surface of the electrode 102). In example 510, pairs of adjacent electrodes 102 may be spaced apart by spacing 102s or pitch 102p, and an inner most electrodes 102′ in each pair may be spaced apart by a distance 102i or a pitch 102j (e.g. as measured between pin 106 centers of electrodes 102′). Spacing 102s, 102i and/or pitches 102p, 102j may be selected to position the electrodes 102 within a target range 520r, when the wire bus 100 is included in a system or device that positions the electrodes into contact with a surface of a body portion, such as skin on a wrist, arm, leg, neck, torso, etc. As one example, target range 520r may be determined by a range of sizes for human wrists ranging from skinny wrists having a small circumference and large wrists having a larger circumference. Although there may be some outlier wrist sizes above and below the target range 520r, the target range 520r may be selected to capture wrist sizes for a majority of a population of users. Target range 520r may encompass a portion of a circumference of those wrists that is positioned on a bottom side of the wrists, for example. Electrodes 102 positioned within the target range 520r may be positioned to sense or otherwise detect structures or properties on the skin or beneath the skin (e.g., subcutaneous). For example, subcutaneous structures may include blood vessels or other tissues associated with the sympathetic nervous system (SNS); whereas, skin conductance may be a property measured by contact of electrodes with a surface of the skin. In some examples, electrodes 102 may be components of a biometric sensor system, such as one that senses bioimpedance (BI). Wire bus 100 may be positioned in a strap band that is mounted to a wrist or other body portion, and as that strap band shifts its position relative to the body portion, the electrodes 102 may be positioned within the target range 520r such that reliable signals may be received from electrodes 102.

Electrode height 102h may be selected to provide sufficient contact pressure between the electrode 102 and a skin surface the electrode 102 is brought into contact with when the strap band or other device that carriers the wire bus 100 is mounted to a body portion, such as an arm or wrist for example. As will be described below, an upper surface of electrode 102 may include a surface area (e.g., X*Y) operative to minimize contact resistance between the electrode 102 and a skin surface it is placed into contact with and/or to improve a signal-to-noise ratio (S/N) of signals generated by the electrode 102. The upper surface of the electrode 102 may have an arcuate shape configured to provide comfort when the electrode 102 is engaged with the body portion and/or to increase surface area of the electrode 102.

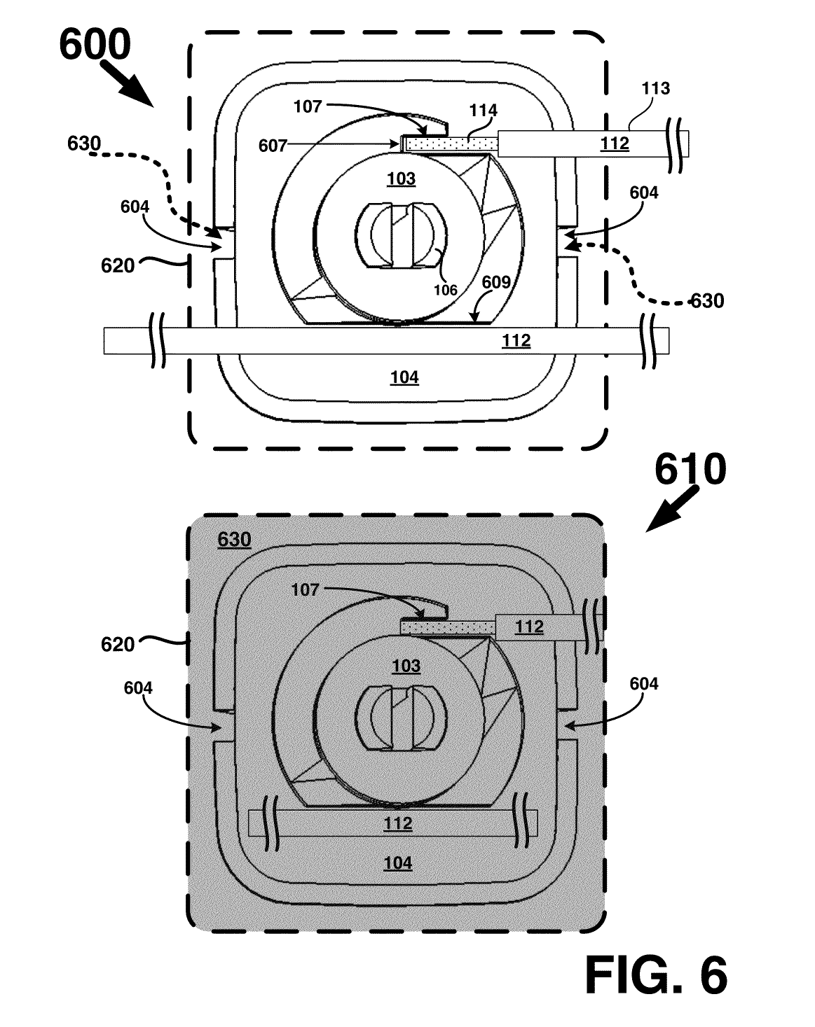

Attention is now directed to FIG. 6 where examples of wire routing and connection with pads 103 included in a wire bus 100 are depicted. In example 600 a back view of skirt 104 and pad 103 includes a flat 609 formed in the pad 103 and operative to allow wire 112 to be routed pass the pad 103 for connection with another pad 103, for example. Pad 103 may include a notch 607 where a stripped end of wire 112 may be positioned for connection of the wire 112 with the pad 103. Skirt 104 may include one or more shot channels 604. Wire bus 100 may be positioned in another structure, such as an inner strap band that includes an aperture denoted by dashed line 620 through which the electrode 102 and its skirt 104 may be disposed. A material may be introduced (e.g., injected as part of an injection molding process) into the shot channels 604 and flow into voids or spaces in the pad 103, skirt 104, pad 103, and into aperture 620. In example 610, the material 630 may fill in and seal a space between the aperture 620 and the skirt 104. The material 630 may also encapsulate structures in the wire bus 100, such as wires 112, portions of pad 103, and portions of skirt 104, for example. Material 630 may be introduced into shot channels 603 via one or more shot ports formed in the wire bus 100 and aligned with shot channels 604 during an injection molding process, for example.

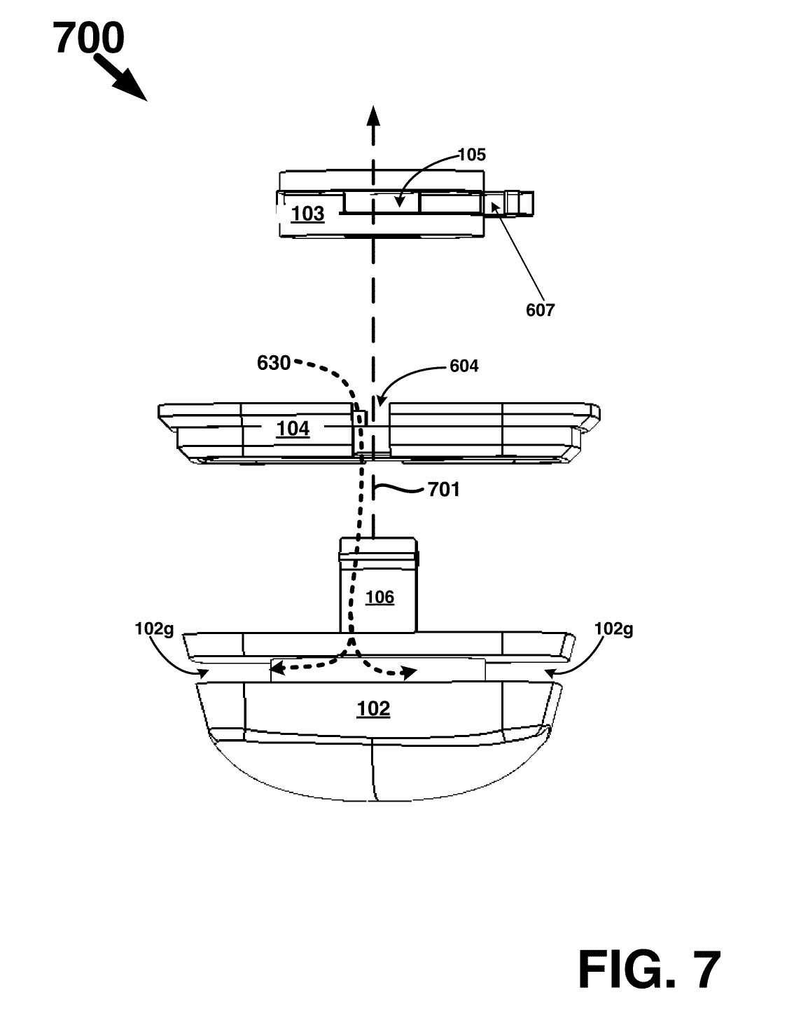

In FIG. 7 a side view 700 depicts one example of an electrode 102, a skirt 104, and a pad 103 that may be included in a wire bus 100. Pin 106 of electrode 102 may be inserted 701 into an aperture 104a of skirt 104 and then into aperture 105 of pad 103. Electrode 102 may include a grooved portion 102g that is positioned in contact with the skirt 104 and may open into one of the shot channels 604. The material 630 (e.g., a thermoplastic elastomer) may flow through shot channels 604 and a portion of the material 630 may flow into grooved portion 102g as well as into other portions (e.g., aperture 620) as was described above.

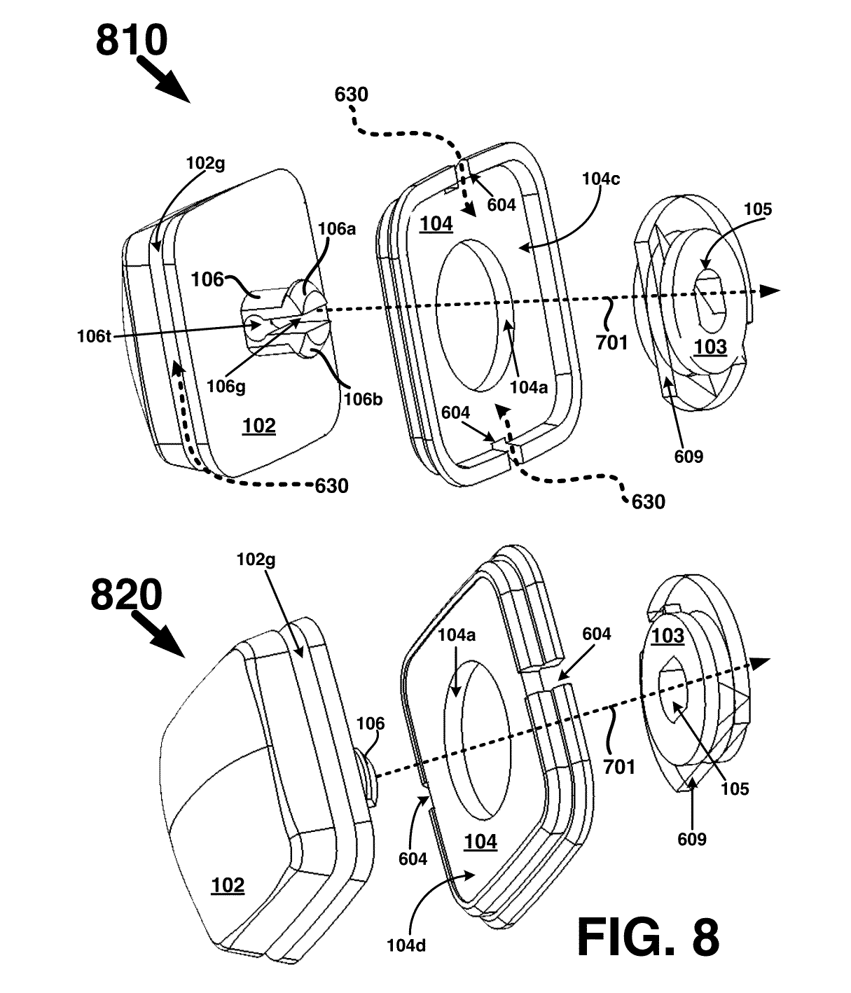

FIG. 8 depicts profile views 810 and 820 of other examples of an electrode 102, a skirt 104, and a pad 103 that may be included in a wire bus 100. Pin 106 of electrode 102 may include a slot 106g that may divide a portion of the pin 106 into sides 106a and 106b. Pin 106 may be inserted 701 through aperture 104a and into aperture 105 of pad 103. Insertion through aperture 105 may cause sides 106a and 106b to deflect inward toward each other and then expand outward away from each other upon exiting the aperture 105. The outward expansion of sides 106a and 106b may exert force against walls of aperture 105 and provide a press fit or friction fit between the pad 103 and the pin 106, such that the electrode 102 is securely coupled with pad 103. The press fit or friction fit may also be operative to securely couple the skirt 104 between the pad 103 and the electrode 102. Front and rear sides of skirt 104 may include recessed portions 104c and 104d. Material 630 may flow into recessed portions 104c and 104d, groove 102g, and into pad 103 via opening 106t in pin 106.

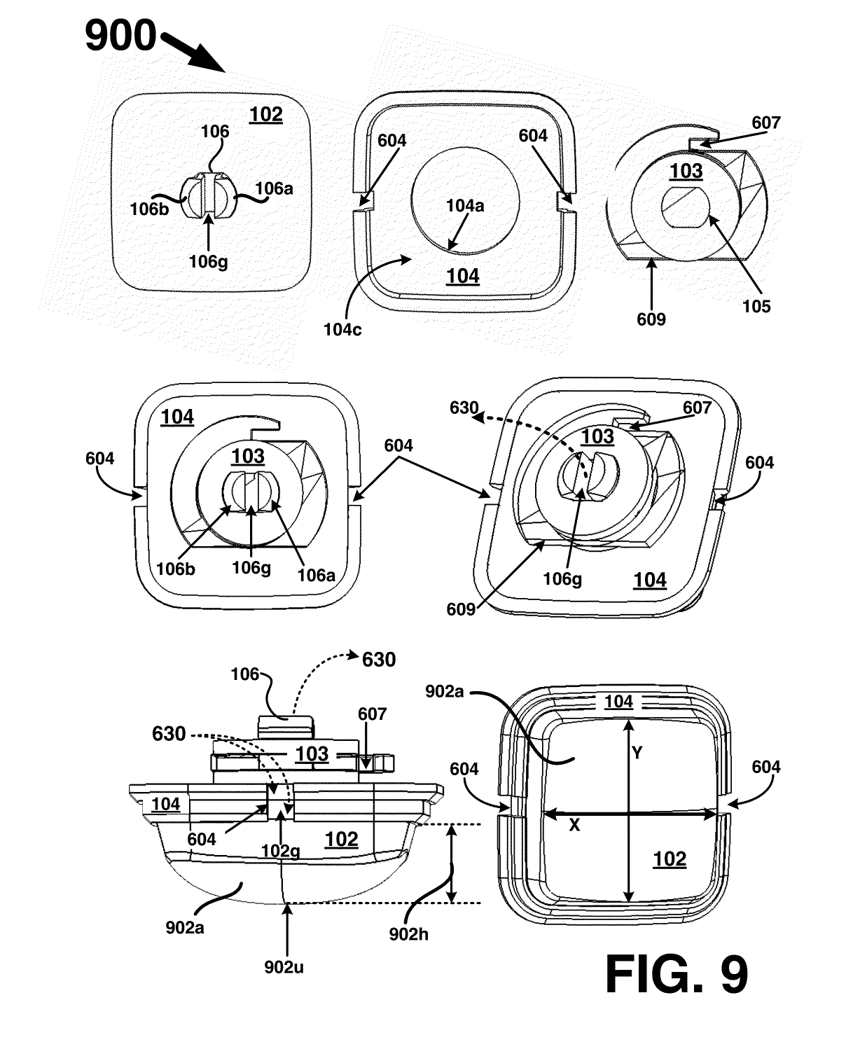

Moving now to FIG. 9 where various views of yet other examples 900 of an electrode 102, a skirt 104, and a pad 103 that may be included in a wire bus 100 are depicted. An uppermost portion 902u of electrode 102 may have a height 902h (e.g., as measured from a top of the skirt or from surface 101a of bus substrate 101) that may be in a range from about 1.0 mm to about 2.5 mm. Height 902h may be determined in part by a thickness of an aperture (e.g., 620) that surrounds the electrode 102 when wire bus 100 is positioned in another structure, such as an inner strap, for example. If a material that forms the aperture is thick (e.g., 2.0 mm thick), then height 902h may be higher than would be the case if the material that forms the aperture is thin (e.g., 1.0 mm thick). In some examples, height 902h may vary among the electrodes 102. For example, one electrode 102 may have a height 902h of approximately 1.5 mm and another electrode 102 may have a height 902h of approximately 1.7 mm.

A surface area 902a of electrode 102 may be in a range from about 8.0 mm² to about 20 mm². For example, surface 902a may have a dimension of about 4.0 mm in a X-dimension and about 4.00 mm in a Y-dimension for an area of about 16 mm². Area for surface 902a may be selected to provide a desired signal-to-noise ratio (S/N) in circuitry coupled with electrode 102 (e.g., via wire 112).

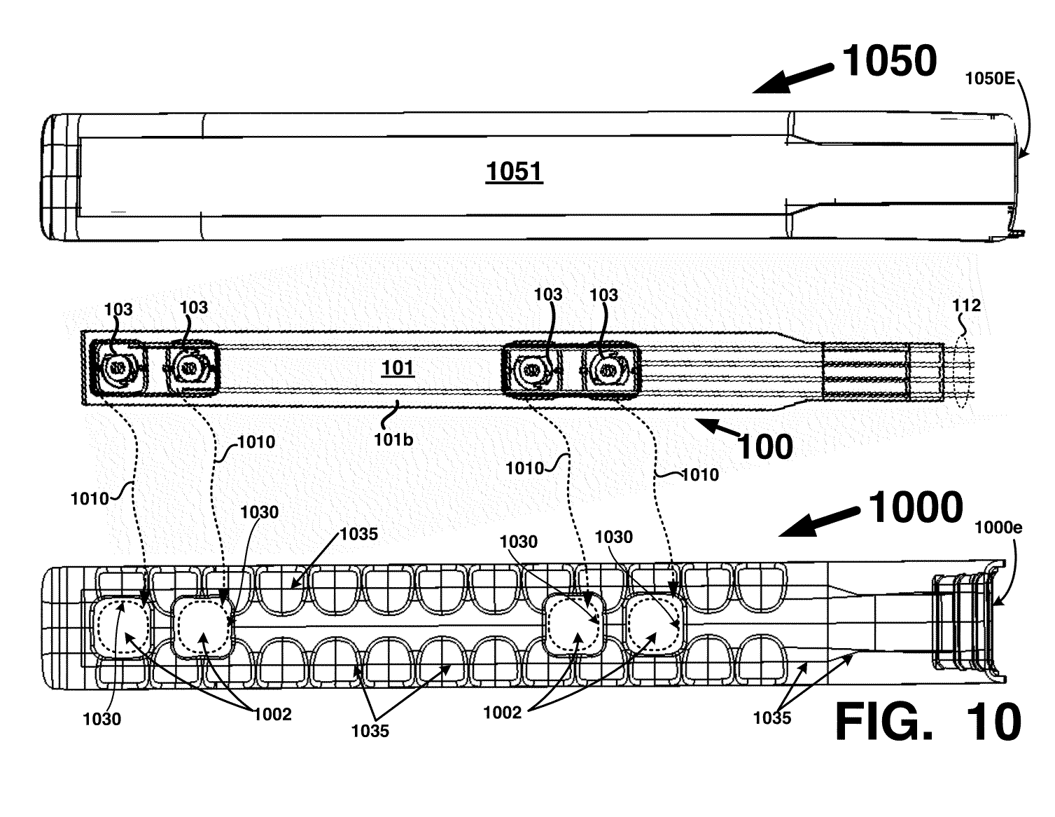

Reference is now made to FIG. 10 where one example of an assembly order of a strap band that includes a wire bus 100, an inner strap 1001 and an outer strap 1050 are depicted. From a backside view of wire bus 100, the wire bus 100 may be positioned in a previously fabricated lower strap 1000. Inner strap 1000 may include a portion 1000e configured to connect inner strap 1000 with another structure or component. Inner strap 1000 may already be connected with another structure or component as part of the previous fabrication. Inner strap 1000 may include apertures 1002 formed in the inner strap 1000 during the previous fabrication. Wire bus 100 may be moved 1010 into position in inner strap 1000 with its electrodes 102 and skirts 104 aligned with apertures 1002 as denoted by dashed lines 1030 which represent an outline of a desired alignment with the apertures 1002 when the wire bus 100 is positioned in the inner strap 1000. Inner strap 1000 may include a cavity 1035 formed during the previous fabrication and configured to receive the wire bus 100. Cavity 1035 may mirror an outline of an outer perimeter of the wire bus 100. The outer strap 1050 will be formed over the connected wire bus and lower strap in a subsequent processing step as will be described below. Outer strap 1050 may also include a portion 1050e configured to connect outer strap 1050 with another structure or component. Portions of surface 101a of bus substrate 101 may include a glue, adhesive or the like applied to surface 101a and operative to facilitate connecting wire bus 100 with inner strap 1000 (e.g., connecting bus substrate with cavity 1035.

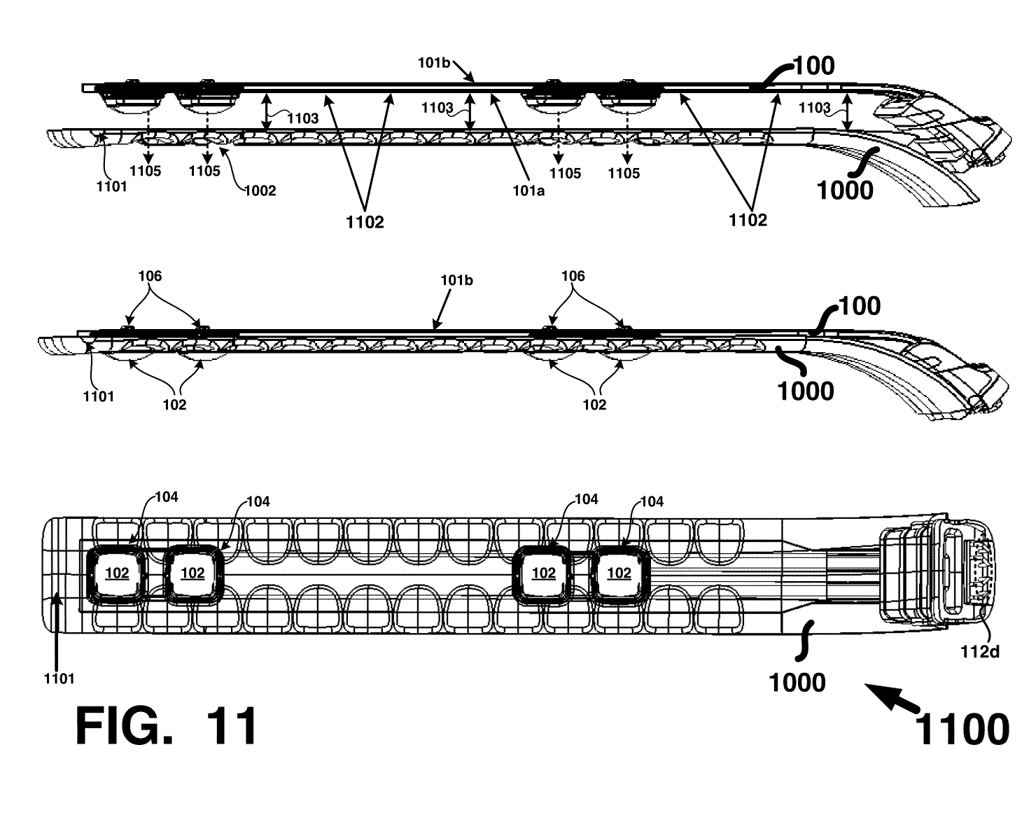

Turning to FIG. 11 where one example of a wire bus 100 being coupled with an inner strap 1000 is depicted. Portions 1102 of surface 101a of bus substrate 101 may have an adhesive or glue applied to surface 101a, for example, a pressure sensitive adhesive tape may be applied to one or more portions 1102 of surface 101a. Wire bus 100 and inner strap 1000 may be brought into contact 1003 with each other with electrodes 102 and skirts 104 aligned 1105 with apertures 1002 as described in reference to FIG. 10. After wire bus 100 is connected with inner strap 1000, electrodes 102 extend outward of their respective apertures 1002, and the wire bus 100 and the inner strap 1000 form sub-assembly 1100.

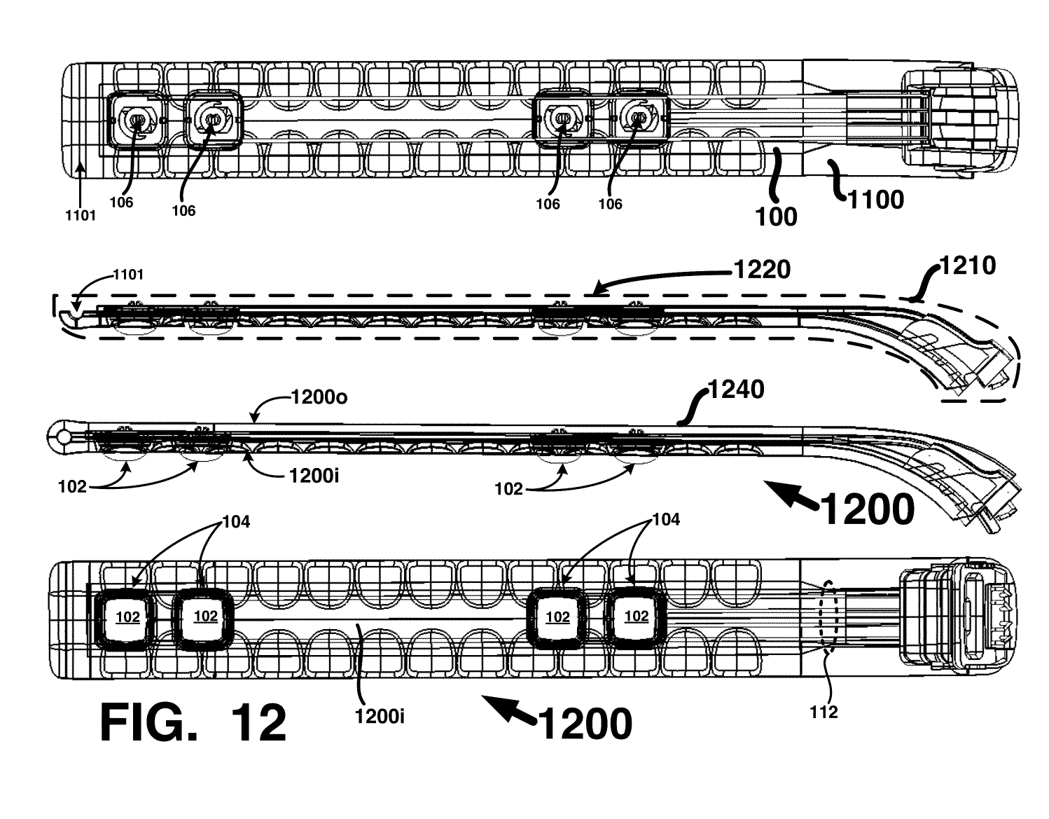

In FIG. 12 one example of an outer strap 1240 being formed on sub-assembly 1100 (e.g., wire bus 100 coupled with an inner strap 1000) is depicted. Sub-assembly 1100 may be positioned in a mold 1210 including features for an outer strap 1240. A material 1220 (e.g., 630) such as a thermoplastic elastomer may be injected into mold 1210 for form the outer strap 1240 around the sub-assembly 1100. The outer strap 1240 and inner strap 1100 may form a strap band 1200 that includes portions of the wire bus 100 encapsulated in the strap band 1200 (e.g., the electrodes 102 extend outward of inner strap 1100). The material 1220 may flow into shot channels 604 of skirts 104 and may seal apertures 1002 as was described above. Inner strap 1100 and outer strap 1240 may be integral with one another after the molding process, such that there may be no visible demarcation of where the inner strap 1100 interfaces with the outer strap 1240. Materials for the inner and outer straps may be the same materials or different materials. Materials for the inner and outer straps may have different colors and may have different surface features or ornamentation. A system may include one or more strap bands, with one of the strap bands being configured as strap band 1200 and another of the strap bands not including the wire bus 100. The system may include two strap bands 1200 with each strap band 1200 having its own encapsulated wire bus 100 and associated wires 112, pads 103, electrodes 102, and skirts 104, for example. The number and placement of electrodes 102 in the two strap bands 1200 may be the same or different (e.g., one strap band 1200 may have four electrodes 102 and the other strap band 1200 may have two electrodes 102). Each strap band in the system may include fastening hardware (e.g., a buckle, a clasp, a latch, etc.) configured to couple the two strap bands with each other and/or to mount the two strap bands to a structure, such as a portion of a human body, such as the arm, the wrist, the leg, the torso, the neck, etc., for example. A system may include two strap bands with each strap band coupled with a device. For example, distal ends of each strap band in the system may couple with a main module that may include structures (e.g., circuitry, PCB traces, etc.) that couple with wires 112 positioned at the distal end or one or both of the strap bands.

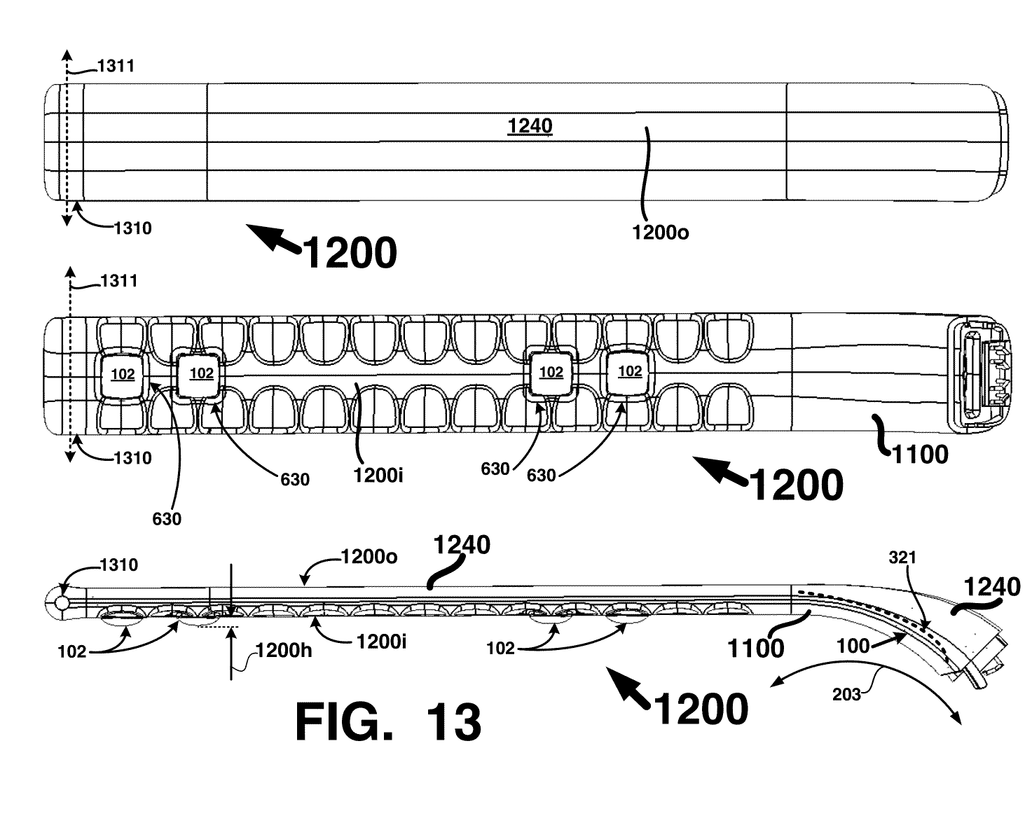

FIG. 13 depicts top, side and bottom views of one example of a strap band 1200 that includes an encapsulated wire bus 100 and sealed electrodes 102. An aperture 1310 configured to accept 1311 fastening hardware for strap band 1200 may be formed by a portion 1101 (e.g., see 1101 in FIGS. 11 and 12) and the molding process of FIG. 12. Strap band 1200 may be flexible 203 as described above. Moreover, prior to the molding of the outer strap 1240, the substrate 321 including the antenna 322 and near field communication chip 320 may be positioned on the wire bus 100. Upper surface 902u of electrodes 102 (see FIG. 9) may extend above a surface 1002i (e.g., an inner surface) of the inner strap 1100 by a height 1200h in a range from about 1.0 mm to about 2.0 mm, for example. In some examples, height 1200h may vary among the electrodes 102. For example, one electrode 102 may have a height 1200h of approximately 0.9 mm and another electrode 102 may have a height 1200h of approximately 1.2 mm. Subsequent to forming the strap band 1200, a demarcation between the inner strap 1100 and outer strap 1240 may not be discernible (e.g., visually) and the inner and outer straps may appear as a single integrated unit.

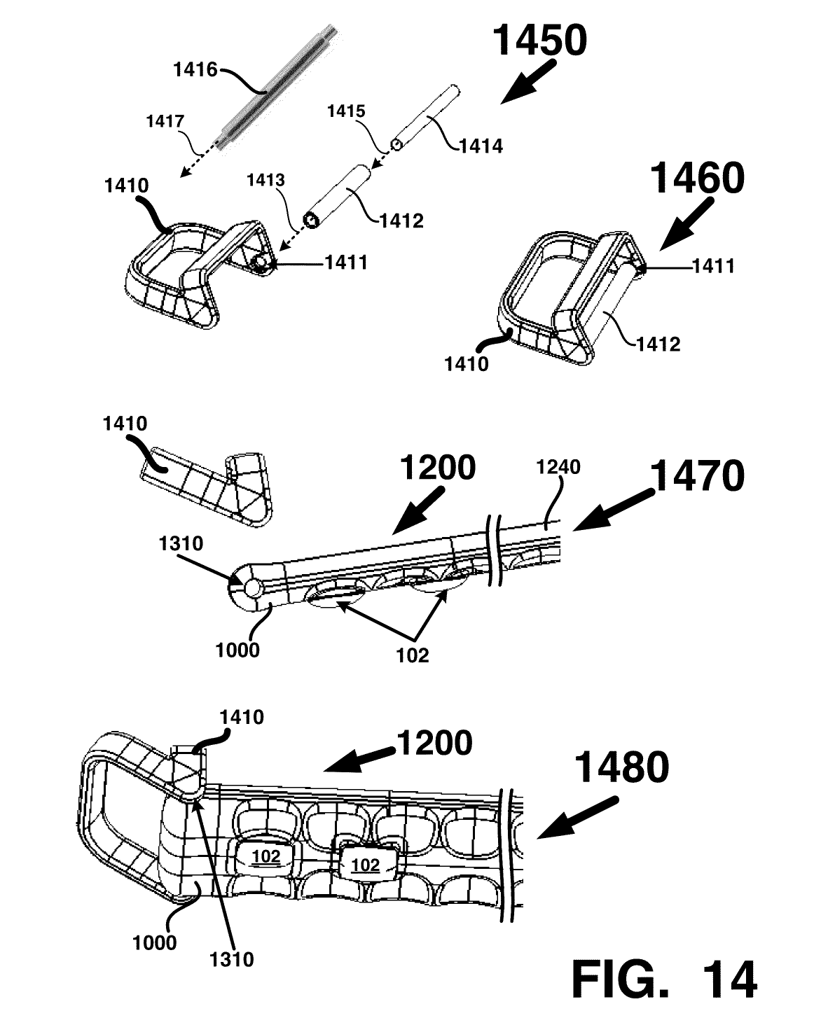

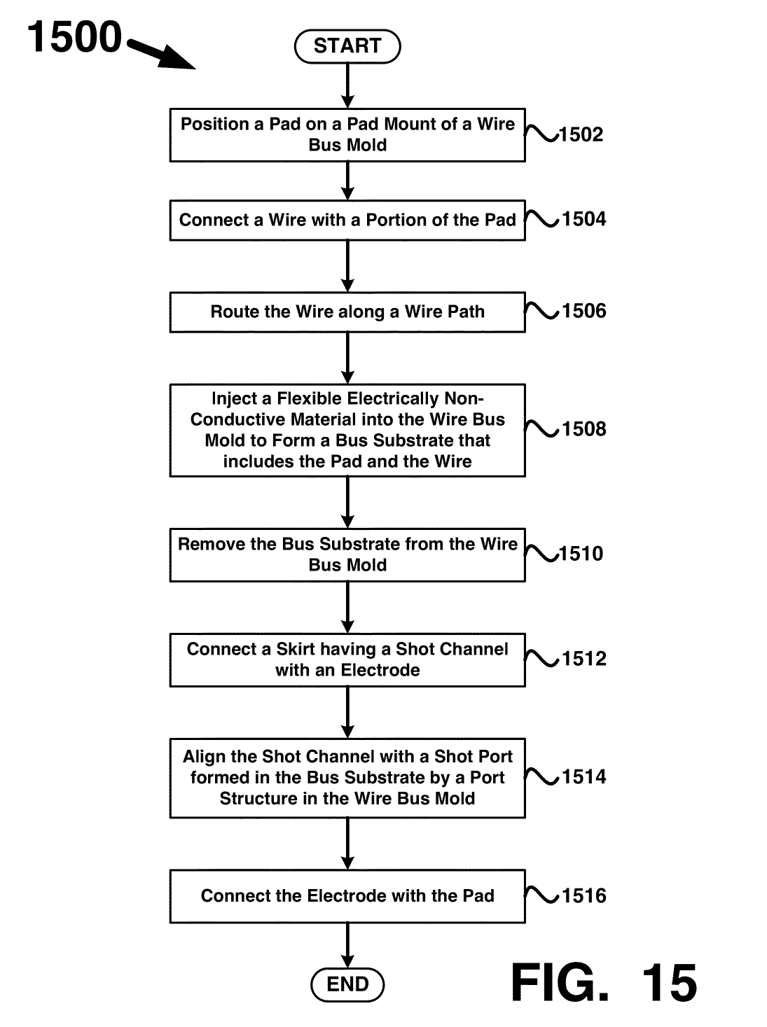

FIG. 14 depicts examples 1450-1480 of fastening hardware that may be coupled with a strap band 1200. In example 1450 a buckle 1410 may include an aperture 1411 through which a sleeve 1412 may be inserted 1413. A pin 1414 may be inserted 1415 into the sleeve 1412 to secure the buckle 1410 to aperture 1310 in the strap band 1200 as depicted in examples 1460-1480. Pin 1414 may be a spring pin or spring bar 1416 (e.g., like those used with watch bands) that may replace pin 1414, sleeve 1412 or both. Spring pin 1416 may include dimensions configured to allow the spring pin 1416 to be inserted 1417 into aperture 1411 of buckle 1410, or if sleeve 1412 is used, then insertion 1417 into sleeve 1412.

Referring now to FIG. 17 were various views 1710-1750 of the strap band 1200 are depicted. Strap band 1200 depicted in views 1710-1750 is just one non-limiting example and strap band 1200 may include more of fewer elements than depicted in FIG. 17 and may have an appearance that differs from the examples depicted in FIG. 17. Strap band 1200 may include one or more colors. Strap band 1200 may include one or more surface finishes (e.g., glossy, flat, matte, etc.). Strap band 1200 may be translucent or transparent (e.g., to reveal structure beneath surfaces 1200o and/or 1200i). After strap band 1200 has been fabricated as described above (e.g., in reference to FIGS. 10-14), inner strap 1100 and outer strap 1240 may not be discernible (e.g., visually discernable) and strap band 1200 may appear as a unitary whole (e.g., no visible seems or structures that would indicate strap band 1200 is composed of inner and outer straps). Strap band 1200 may include surface features and/or ornamentation (e.g., for esthetic purposes) on outer surface 1200o and/or inner surface 1200i, for example. Although views 1710-1750 depict dressed wires 112d, actual configurations for the wires 112 may be application dependent and are not limited to the exampled depicted herein.

In views 1710-1750, the buckle 1410 is depicted attached to strap band 1200; however, the strap band 1200 need not include the buckle 1410 and the types of fastening hardware that may be coupled with strap band 1200 are not limited to examples depicted herein. Although actual dimensions for strap band 1200 may be application dependent, strap band 1200 may have a width 1721 (see view 1720) in a range from about 8 mm to about 15 mm, for example. In some examples, a width of the strap band 1200 may vary along a length of the strap band 1200. For example, strap band 1200 may be wider at the buckle 1410. Width 1721 may be the smallest width of strap band 1200, for example. A thickness of strap band 1200 may vary along a length of the strap band 1200 (e.g., strap band 1200 may be thicker at distal end 109); however, notwithstanding the height 1200h of the electrodes 102 above surface 1200i, strap band 1200 may include a thickness 1731 (see view 1730) in a range from about 0.9 mm to about 3.2 mm, for example. Strap band 1200 may include thickness 1731 along portions of the strap band 1200 that are positioned into contact with a body portion of a user when a device that includes strap band 1200 is worn by the user, such as a portion of an arm adjacent to a wrist of the user. Thickness 1731 may be selected to be the thinnest portion of strap band 1200.

FIG. 15 depicts one example of a flow diagram 1500 for a method of fabricating a wire bus 100. At a stage 1502 a pad (e.g., 103) may be positioned on a pad mount (e.g., 130) of a wire bus mold. At a stage 1504 a wire (e.g., 114 of 112) may be connected with a portion of the pad. At a stage 1506 the wire may be routed along a wire path. At a stage 1508 a flexible electrically non-conductive material (e.g., a thermoplastic elastomer) is injected into the wire bus mold to form a bus substrate (e.g., 101) that includes one or more pads with each pad having a wire connected to it. At a stage 1510 the bus substrate may be removed from the wire bus mold. At a stage 1512, a skirt (e.g., 104) having a shot channel (e.g., 604) may be connected with an electrode (e.g., 102). At a stage 1514 the shot channels in the skirts may be aligned with a shot port formed in the bus substrate by a port structure in the wire bus mold. At a stage 1516 the electrode may be connected with the pad (e.g., the electrode 102 with its connected skirt 104).

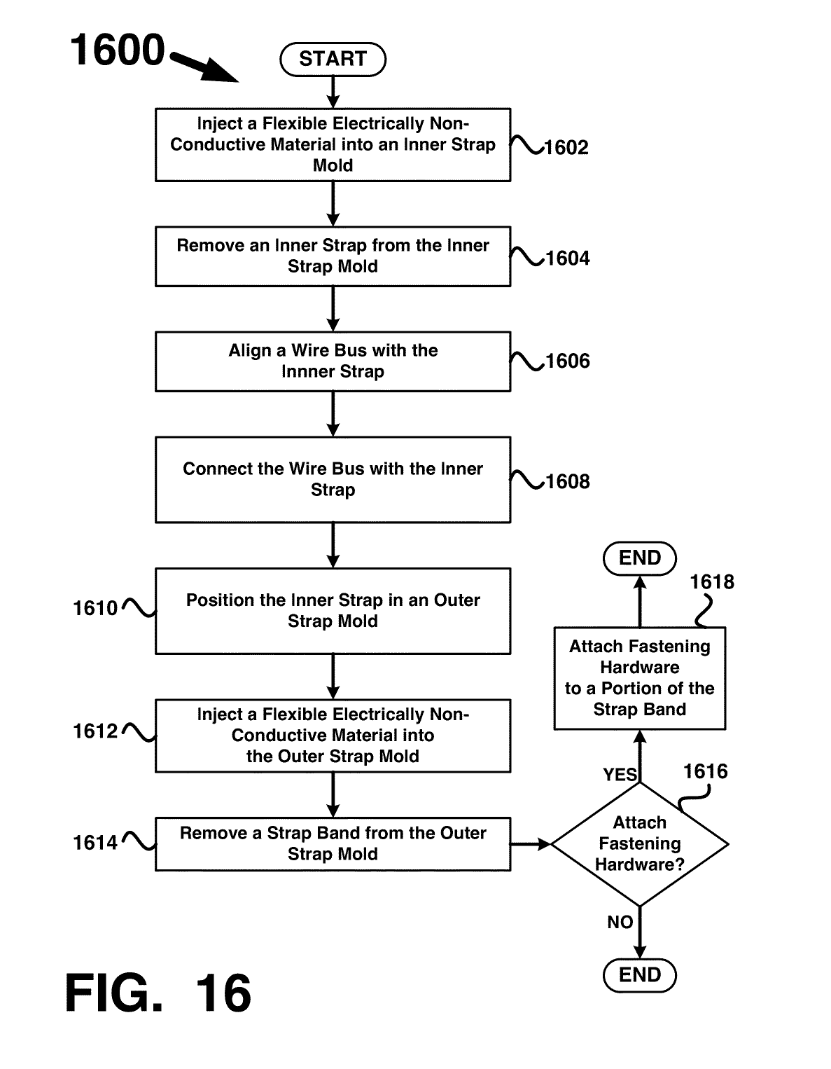

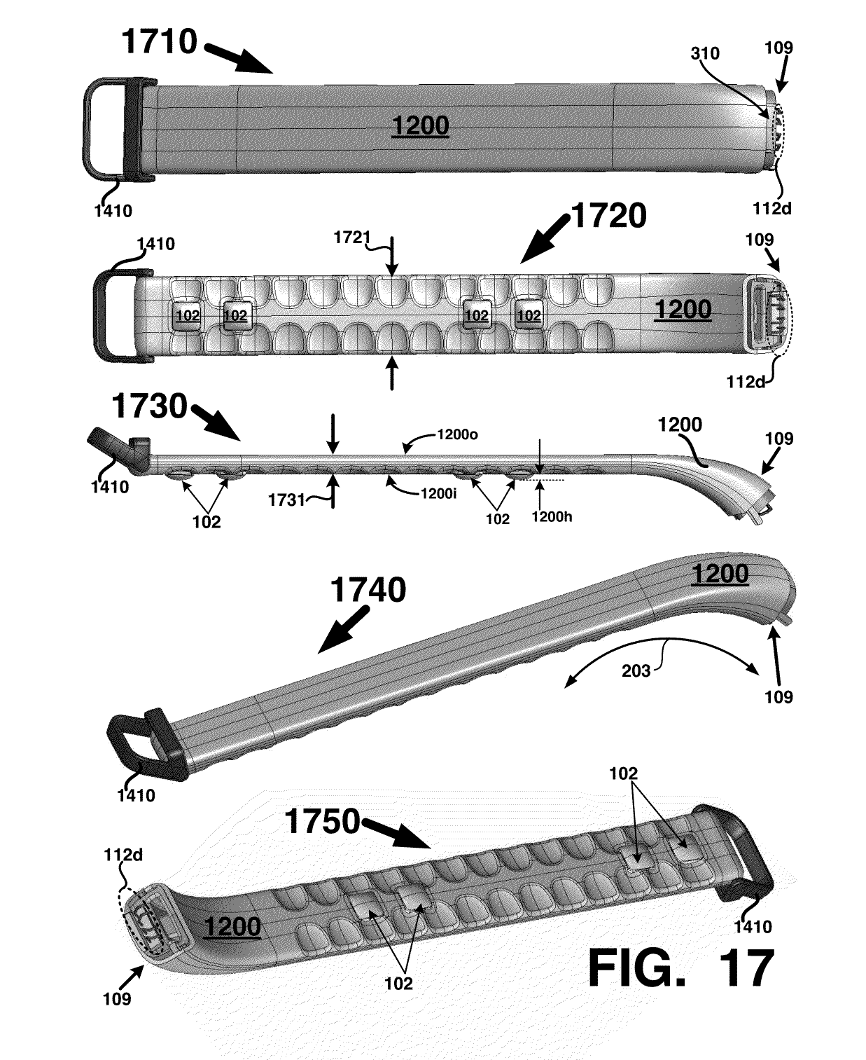

FIG. 16 depicts one example of a flow diagram 1600 for a method of fabricating a strap band (e.g., 1200) that includes a wire bus 100. At a stage 1602 a flexible electrically non-conductive material (e.g., a thermoplastic elastomer) may be injected into an inner strap mold. At a stage 1604 an inner strap (e.g., 1000) may be removed from the inner strap mold. At a stage 1606 a wire bus (e.g. 100) may be aligned with the inner strap. At a stage 1608 the wire bus may be positioned into contact with the inner strap while maintaining alignment between the wire bus and the inner strap. At a stage 1610 the inner strap and its connected wire bus (e.g., sub-assembly 1100) may be positioned in an outer strap band mold. At a stage 1612 a flexible electrically non-conductive material (e.g., a thermoplastic elastomer) may be injected into the outer strap mold. At a stage 1614 a strap band may be removed from the outer strap mold. At a stage 1616 a decision may be made as to whether or not to attach fastening hardware (e.g., 1410, 1412, 1414) to the strap band. If a NO branch is taken, then the flow 1600 may terminate. On the other hand, if a YES branch is taken, then flow 1600 may transition to another stage, such as a stage 1618, for example. At the stage 1618, the fastening hardware is attached to a portion of the strap band.

Although the foregoing examples have been described in some detail for purposes of clarity of understanding, the above-described inventive techniques are not limited to the details provided. There are many alternative ways of implementing the above-described techniques or the present application. The disclosed examples are illustrative and not restrictive.

What is claimed is:

1. A wire bus, comprising:
a plurality pads;
a plurality of wires, each wire connected with one of the pads;
a plurality of electrodes;
a plurality of skirts, each skirt having a shot channel,
each electrode connected with one of the pads and one of the skirts; and
a bus substrate including a plurality of alignment structures and a plurality of shot ports with each shot port aligned with the shot channel of one of the skirts, the skirts and a portion of the electrodes are positioned above a first surface of the bus substrate, and a first portion of the plurality of wires is encapsulated by the bus substrate and a second portion of the plurality of wires is positioned at a distal end of the bus substrate.

2. The wire bus of claim 1 and further comprising:
a substrate mounted on the bus substrate, the substrate including an antenna and a near field communication chip coupled with the antenna.

3. The wire bus of claim 1, wherein each wire comprises an insulating outer layer, a conductor layer surrounded by the insulating outer layer, and a core layer surrounded by the conductor layer.

4. The wire bus of claim 1, wherein each electrode includes an upper surface having a distance above the first surface that is in a range from about 1.6 mm to about 2.2 mm.

5. The wire bus of claim 1, wherein an upper surface of each electrode is non-planar.

6. The wire bus of claim 1, wherein the bus substrate is made from a thermoplastic elastomer and the skirts are made from a polycarbonate.

7. The wire bus of claim 1, wherein an upper surface of each electrode includes a surface area in a range from about 10 mm² to about 16 mm².

8. The wire bus of claim 1, wherein the plurality of electrodes comprises a pair of adjacent electrodes that are spaced apart from each other by a distance of about 4.0 mm.

9. The wire bus of claim 1, wherein the plurality of electrodes comprises a first pair of adjacent electrodes that are spaced apart from each other by a first distance of about 4.0 mm, a second pair of adjacent electrodes that are spaced apart from each other by a second distance of about 4.0 mm, and an innermost electrode in the first pair is spaced apart from an innermost electrode in the second pair by a third distance of about 36.0 mm.

10. The wire bus of claim 1, wherein each electrode has a dimension of about 4.5 mm on a side.

11. The wire bus of claim 1, wherein each pad includes an aperture, each electrode includes a pin, and each electrode is coupled with one of the pads by a press fit between the aperture and pin.

12. The wire bus of claim 1 and further comprising:
a pressure sensitive adhesive positioned on the first surface of the bus substrate, a second surface of the bus substrate or both.

13. The wire bus of claim 1, wherein each skirt is positioned between one of the electrodes and one of the pads.

14. A method of fabricating a wire bus, comprising:
positioning a pad on a pad mount in a wire bus mold;
connecting a wire with a portion of the pad;
routing the wire along a wire path to a distal end of the wire bus mold;
positioning the wire bus mold in an injection molding system;
injecting, using the injection molding system, a flexible electrically non-conductive material into the wire bus mold, the material covering a first portion of the wire, portions of the pad adjacent to the pad mount are not covered by the material, the injecting operative to form a bus substrate that includes the pad, the wire and a shot port adjacent to the pad and formed by a port structure positioned in the wire bus mold;
removing the bus substrate from the wire bus mold;
connecting a skirt with an electrode;
aligning a shot channel in the skirt with the shot port; and
connecting the electrode with the pad.

15. The method of claim 14, wherein the flexible electrically non-conductive material comprises a thermoplastic elastomer and the skirt comprises a polycarbonate material.

16. The method of claim 14 and further comprising: pressing a pin of each electrode into an aperture of one of the pads, the pressing operative to form a press fit between the pin and the pad.

17. A system, comprising:
a wire bus including a plurality of wires, a plurality of pads, and a plurality of electrodes, each wire coupled with one of the pads, each pad coupled with one of the electrodes, each electrode coupled with a skirt;
a first strap band; and
a second strap band, the wire bus encapsulated in the first strap band, the second strap band or both with each electrode extending outward of an inner surface of the strap band the wire bus is encapsulated in,
the first and second strap bands are made from a material operative to interact with a first material of the skirt to form a seal around each electrode, the skirt coupled with the electrode and the inner surface, and each wire routed along a path in the wire bus from one of the pads to a distal end of the strap band the wire bus is encapsulated in.

18. The system of claim 17, wherein the first material is operative to provide a mechanical interface between the skirt, the electrode and the material.

19. The system of claim 17, wherein the wire bus is made from a second material configured to allow relative motion between the wire bus and the strap band it is encapsulated in when a load force is applied to the strap band.

20. The system of claim 17, wherein each electrode includes a non-planar upper surface having a distance above the inner surface that is in a range from about 1.0 mm to about 2.0 mm.
